(19) United States
(12) Patent Application Publication
(10) Pub. No.: US 2008/0233663 A1
(43) Pub. Date: Sep. 25, 2008

(54) SINGULATED BARE DIE TESTING

(75) Inventors: Robert Norbeck, Sunnyvale, CA (US); Mark Ojeda, Sunnyvale, CA (US); Ed Aquino, Sunnyvale, CA (US)

Correspondence Address: AMIN, TUROCY & CALVIN, LLP, 1900 EAST NINTH STREET, 24TH FLOOR, NATIONAL CITY CENTER, CLEVELAND, OH, 44114, US

(73) Assignee: SPANSION LLC, Sunnyvale, CA (US)

(21) Appl. No.: 11/835,545

(22) Filed: Aug. 8, 2007

Related U.S. Application Data
(60) Provisional application No. 60/895,920, filed on Mar. 20, 2007.

(51) Int. Cl. H01L 21/66; G01R 31/02

(52) U.S. Cl. 438/14; 324/765; 257/E21.525

(57) ABSTRACT

There is testing of individual dice prior to their inclusion in a multi-chip package. A wafer is sawn into individual dice and the dice are placed onto a die tray. If the tray is not full, then dice can be added that originate from other wafers. Contacts perform diagnostic tests upon the dice to determine if individual dice function as expected. Mapping talkes place to distinguish between dice that passed the diagnostic test and those that did not. Multiple tests can take place in series, where various forms of consolidation and mapping takes place. Passing dice can become part of a multi-chip package while failing dice can be re-screened or scrapped.

### CROSS-REFERENCE TO RELATED APPLICATIONS

This application claims the benefit of Provisional U.S. Patent Application Ser. No. 60/895,920, filed Mar. 20, 2007, the entirety of which is herein incorporated by reference.

### TECHNICAL FIELD

Disclosed herein is information relating in general to memory cell construction and in particular to testing wafer portions prior to construction of a multi-die package.

### BACKGROUND

The development of computer technology allows for a large amount of information to be processed and stored in a relatively small physical space. Computer technology influences various facets ranging from interpersonal communication to mass dissemination of information; moreover, many electronic devices utilize computer technology though a processing unit.

One area of development in computer technology is the use of silicon wafers for processing information. Initially, large amounts of semi-conductor materials (e.g., silicon, germanium, etc.) are grown. In one configuration of creating a semi-conductor wafer, the semi-conductor material is melted into a thick, liquid form and stored in a specially designed cup, commonly made of quartz.

A small piece of crystal made of the same semi-conductor material is dipped into the semi-conductor material liquid. The piece of crystal is pulled away from the liquid and while the piece of crystal is pulled away, it is turned. The process creates a relatively large, single, semi-conductor material called ingot, which commonly includes a cylinder and cone portion. The cylinder is then sliced into individual wafers. While the process is a common process for creating a semi-conductor wafer, other methods can be employed. For example, employment of temperature manipulation of the semi-conductor can also create the ingot.

### SUMMARY

The following discloses a simplified summary of the innovation in order to provide a basic understanding of some aspects of the innovation. This summary is not an extensive overview of the innovation. It is intended to neither identify key or critical elements of the innovation nor delineate the scope of the innovation. Its sole purpose is to disclose some concepts of the innovation in a simplified form as a prelude to the more detailed description that is disclosed later.

Disclosed is information for creating of a multi-chip package. In conventional multi-chip packages, individual dice are attached together and then tested. However, if one die in the multi-chip package is considered a ‘bad’ die (e.g., a die that does not meet certain parameters), then the entire multi-chip package is considered ‘bad’ and the package is not used. The disclosed innovation tests each die prior to its attachment to a multi-chip package. This minimizes the number of ‘good’ die that are eliminated.

A wafer divides into smaller wafer portion (otherwise known as die) that are placed onto a tray. Commonly there are not an equal number of wafer portions for slots on a tray, so a consolidator fills the tray with wafer portions from different wafers to create full trays. A tester performs diagnostics on the wafer portions to determine whether they function as expected. Mapping takes place to distinguish between wafer portions that passed the test and wafer portions that failed the test. Wafer portions are separated based on their outcome of test. Successful dice enter a multi-chip package while unsuccessful cells are either re-screened or discarded.

The following description and the annexed drawings set forth certain illustrative aspects of the innovation. These aspects are indicative, however, of but a few of the various ways in which the principles of the innovation may be employed. Other advantages and novel features of the innovation will become apparent from the following detailed description of the innovation when considered in conjunction with the drawings.

### BRIEF DESCRIPTION OF THE DRAWINGS

FIG. 1 illustrates an example multi-chip package creation system with regard to an aspect of the disclosed innovation.

FIG. 2 illustrates an example die testing system with regard to an aspect of the disclosed innovation.

FIG. 3 illustrates an example loader cell with regard to an aspect of the disclosed innovation.

FIG. 4a illustrates an example wafer with regard to an aspect of the disclosed innovation.

FIG. 4b illustrates an example diced wafer with regard to an aspect of the disclosed innovation.

FIG. 4c illustrates an example partially filled tray with regard to an aspect of the disclosed innovation.

FIG. 5 illustrates an example consolidator cell with regard to an aspect of the disclosed innovation.

FIG. 6 illustrates an example tester with regard to an aspect of the disclosed innovation.

FIG. 7 illustrates an example sorter cell with regard to an aspect of the disclosed innovation.

FIG. 8 illustrates an example media transfer cell with regard to an aspect of the disclosed innovation.

FIG. 9a illustrates a first part of an example die testing methodology with regard to an aspect of the disclosed innovation.

FIG. 9b illustrates a second part of an example die testing methodology with regard to an aspect of the disclosed innovation.

FIG. 9c illustrates a third part of an example die testing methodology with regard to an aspect of the disclosed innovation.

FIG. 10 illustrates an example multi-chip construction methodology with regard to an aspect of the disclosed innovation.

FIG. 11 illustrates an example of a schematic block diagram of a computing environment in accordance with the disclosed innovation.

FIG. 12 illustrates an example of a block diagram of a computer operable to execute the disclosed architecture.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

As used in this application, the terms “component,” “module,” “system”, “interface”, or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers. As another example, an interface can include I/O components as well as associated processor, application, and/or API components.

Furthermore, the claimed subject matter may be implemented as a method, apparatus, or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ). Additionally it should be appreciated that a carrier wave can be employed to carry computer-readable electronic data such as those used in transmitting and receiving electronic mail or in accessing a network such as the Internet or a local area network (LAN). Of course, those skilled in the art will recognize many modifications may be made to this configuration without departing from the scope or spirit of the claimed subject matter.

Moreover, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to disclose concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

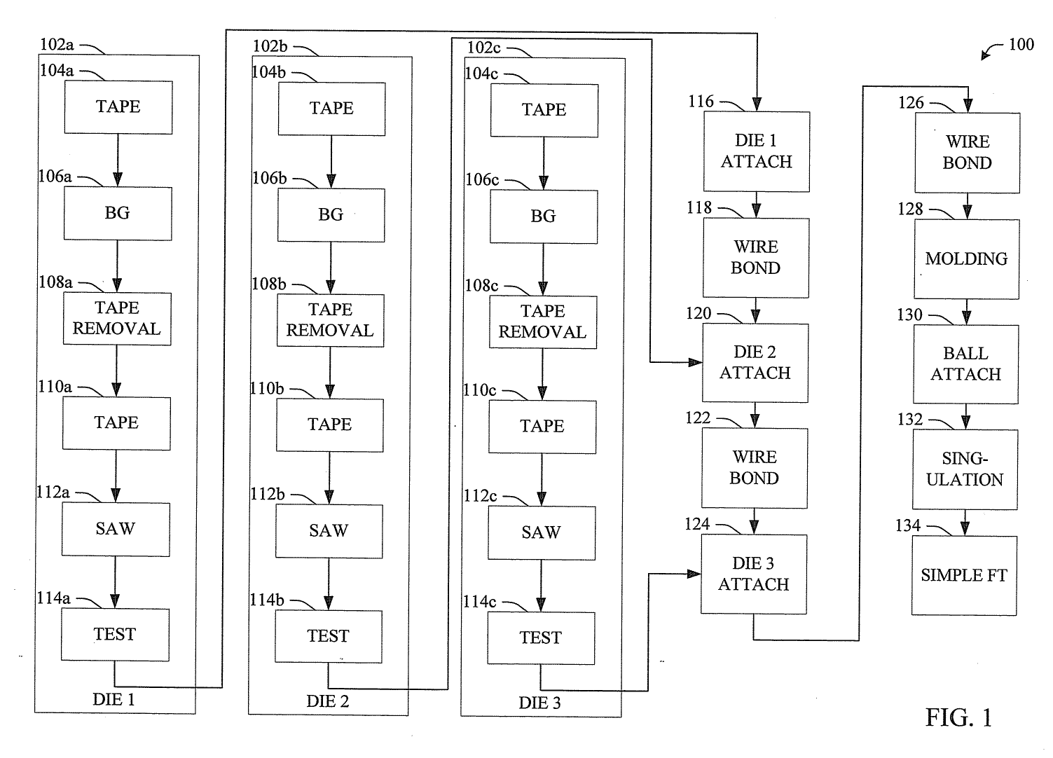

FIG. 1 discloses an example system 100 of creating a multi-chip package (MCP). An MCP is a component that includes two or more die. Initially, a wafer is manufactured in a manner in which to create a number of individual die from the wafer. Commonly, wafers have a diameter of about eight inches to about 12 inches or about 200 millimeters (mm) to about 300 mm. The system 100 discloses three similar mechanisms for wafer 102a, 102, and 102c. It is to be appreciated that while three die are discloses, there can be numerous different dice attached in a multi-chip package. Different wafers can have different individual properties. Therefore, it can be desirable to have different die with different properties in a single MCP. Each mechanism 102a-102c can be for different wafer types.

A common wafer can have one clean side and one side with exposed devices (e.g., die pads, circuitry, etc. . . . ) Tape is applied to an exposed side of a wafer 104a, 104b, and 104c. Once there is application of tape, the clean side is background to a desired thickness 106a, 106b, and 106c. There are numerous benefits to backgrinding a wafer and thus the die created from the wafer.

Having dice that are of a uniform thickness allows for easier operation. If each die is of a uniform thickness with a tolerance, then operations can be created with more precision since the thickness of the die is known. For example, machines that operate upon the dice can have a maximum height requirement. Backgrinding allows the machines to operate upon the die. Furthermore, a smaller die depth allows more dice to stack together in an MCP.

The tape is removed from the exposes side 108a, 108b, and 108c and tape is applied to the clean side 110a, 110b, and 110c. The wafer is then divided into individual dice 112a, 112b, and 112c. Commonly, dice are created ranging in size from about three mm to about 15 mm. In addition, there can be an ability to test devices with a die pad size ranging from about 40 micrometers (atm) to about 70 μm, where the saw divides dice along spaces between the die, otherwise known as streets.

Division can take place using various embodiments. According to one embodiment, a saw is employed to divide the wafer into individual dice. Wafers are background to a final thickness before sawing the wafer into wafer portions. Sawcut accuracy allows for alignment to a corner edge to determine where to locate die pads. There is a plus/minus ten μm tolerance to a center of a die in determining where to place the sawcut. Positional tolerance has plus/minus five Jim to gaps left by the saw. In addition, there can be a tolerance of plus/minus five μm for a thickness width of the saw blade.

According to another embodiment, a laser divides the wafer into individual dice. In yet a further embodiment, a laser/liquid hybrid divides the wafer into die portions. The liquid can be a number of different liquids, such as lubricant, coolant, etc.

Once the dice are divided 112a, 112b, and 112c, a test takes place for individual dice 114a, 114b, and 114c. Typically, this is the first test performed on the wafer and/or die. This differs from conventional construction of an MCP in that dice are more rigorously tested prior to the construction of the MCP. While there is representation of an individual test 114a, 114b, and 114c, it is to be appreciated that a number of tests can take place prior to application with an MCP. Common tests are diagnostic tests that determine if a die functions in an expected manner. Examples of tests that can take place are a sort test, final test, or built in self-test.

A first die is attached to a base (e.g., substrate) 116 that will ultimately become an MCP. The first die is then wire bonded 118 with the base, where the wire bond is the communication link between the first die and the base. The second die is attached to the base 120 and wire bonded to the base 122. The third die is also attached to the base 120 and wire bonded 126. The three die with wires can be considered as a stack.

The stack is molded 128, which allows the stack to be encapsulated. For example, the encapsulation can surround the stack in plastic to protect the stack from environmental elements. At least one ball then attaches to the base 130 where the ball allows the base to communicate with another device. The ball commonly attaches on the other side of the base on a pad which is electrically connected to a bond wire.

According to one embodiment, the base comes as a strip of substrate. For example, the strip can be about six units by about six units, for about 36 units. Singulation 132 takes place, which divides the strip into individual parts. A simple final test 134 can take place to determine if there is an error in the created MCP. For example, a test can determine if the wire bonds were created correctly.

It is to be appreciated that there are other manner in which to construct an MCP. For example, die attachment 116, 118 and 120 as well as wire bond 118, 122, and 126 can be replaced by other embodiments. According to one example, dice 102a, 102b, and 102c can attach directly to one another without attachment to a base.

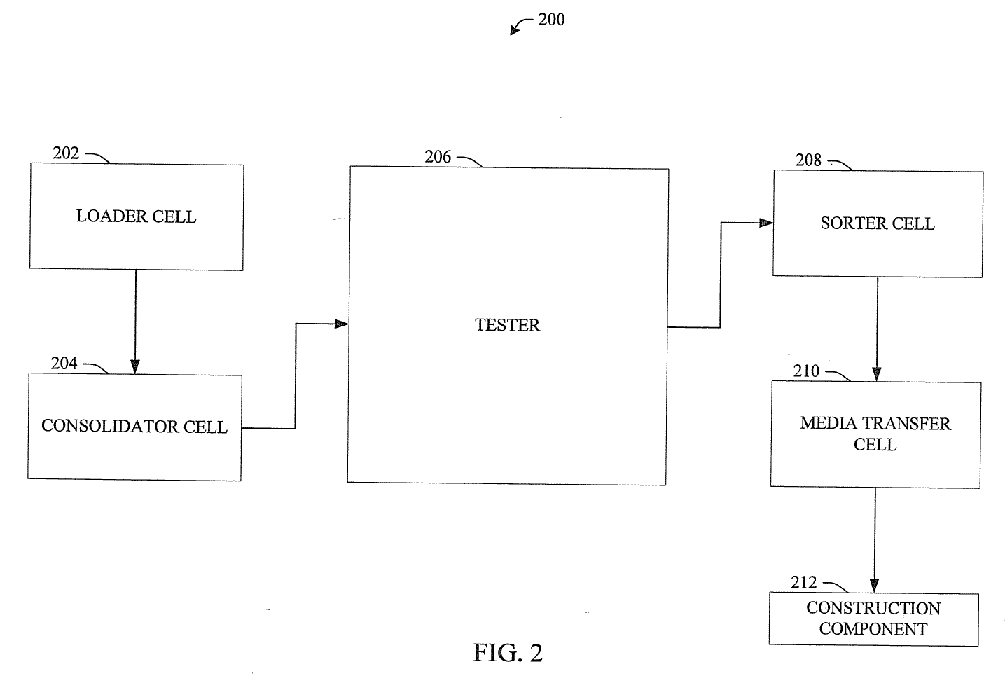

FIG. 2 discloses an example system 200 for testing die. The system can at least in part represent functions of a test 114a, 114b, and 114c of FIG. 1. Diced wafers, otherwise known as dice, enter a loader cell 202 for placement and organization that relates to further testing. Commonly, upon entering the loader cell, dice are removed from tape and placed onto a wafer tray. The diced wafer portions originate from an assembly area that divided an original wafer into smaller portions.

Dice transfer to a consolidator cell 204. At the consolidator cell, the dice from the loader cell 202 can combine with wafer dice from previous batches. This allows the wafer trays to be filled so there is maximum capacity. The wafer trays transfer to a tester 206 where individual dice are tested to determine if a die is viable for use in an MCP. Testing of dice can take place at a high frequency with various temperatures (e.g., hot, cold, room, etc. . . . )

Tested dice transfer to a sorter cell 208 where dice are differentiated between successfully tested die (e.g., dice that meet testing requirements) and unsuccessfully tested dice (e.g., dice that did not meet testing requirements.) Dice that are successfully tested can move to the consolidator cell 204, to another testing system, to a media transfer cell 210, or remain in the sorter cell 208 for consolidation. Unsuccessful cells can either be eliminated or re-screened to determine why the unsuccessful cell did not pass test performed by the bare die test cell.

Multiple systems for testing die can be lined together in series. For example, the tester 206 can operate a sort test. If another test is to take place, the successful cells can transfer to a tester, loader cell, or consolidator cell of another system. Once the tests are performed, completed trays (e.g., trays filled with successful die) transfer to a media transfer cell 210 where dice are prepared for final application into an MCP.

A construction component 212 creates an MCP from die diagnostically examined by the tester 206. According to one embodiment, other systems can send die to the construction component 212. The construction component 212 creates an MCP with different dies; for example, two different die sets can be tested independently (e.g., not at the same time) and the MCP can include a die from the two die sets. In another embodiment, the construction component 212 holds dice produced by the system 200. Another die type can process through the system 200 and the construction component can combine multiple die types (e.g., 102a and 102b from FIG. 1.) According to one embodiment, the system 200 operates at a rate of about 30,000 units per hour.

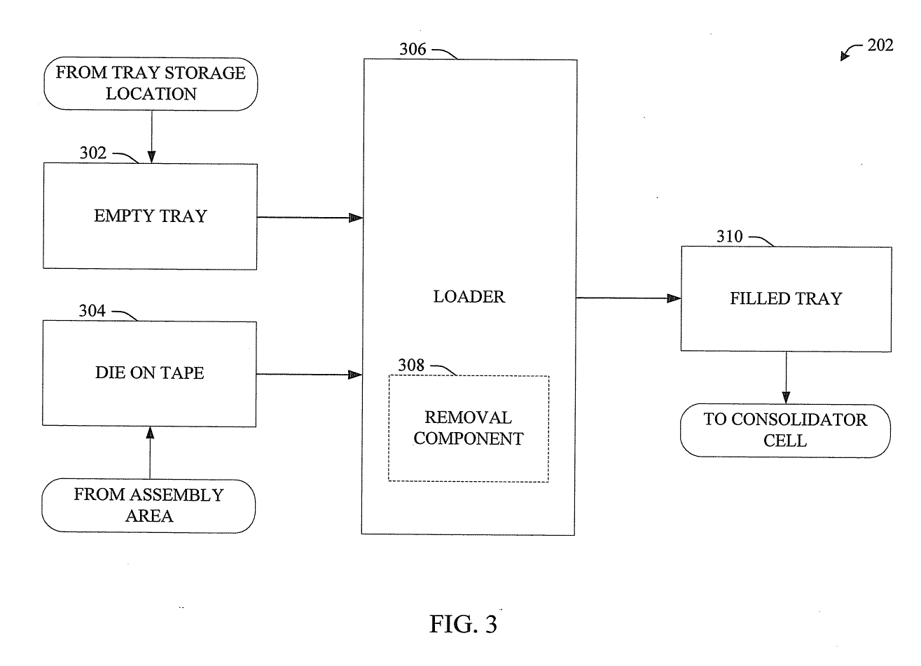

FIG. 3 discloses an example loader cell 202 of FIG. 2. An empty tray 302 for bare die tested is selected for use by the loader cell 202. The empty tray 302 can have the space for various numbers of dice. For example, an empty tray can hold about 1024 dice (e.g., about 32 dice by about 32 dice). However, it is possible that the tray can hold other values, for example, about 256 dice. The tray should be planar to about plus/minus one μm at the test site area and be usable for different die sizes. The empty tray 302 can originate from a number of different locations. In one embodiment, the loader cell 202 has an internal compartment where empty trays 302 are stored. In another embodiment, there is a common area outside of the loader cell 202 where multiple components can retrieve an empty tray 302; the loader cell 202 obtains an empty tray from the common area.

The loader cell 202 also obtains a number of dice that are located on a piece of tape 304. In a dicing component (e.g., 112a, 112b, and 112c of FIG. 1,) one wafer is diced into a number of different dice. According to one embodiment, the dice are the same size and shape; commonly rectangular shaped. For example, a relatively large, circular wafer is diced into mostly relatively small squares (e.g., square wafer portions.) The squares transfer into the loader cell while non-uniform dice (e.g., edge wafer portions) are disregarded.

The empty tray 302 and wafer portions enter into a loader 306. The loader 306 can contain a removal component 308 that removes dice from the tape and places dice onto the empty tray 302 creating a filled tray 310 (e.g., partially filled tray, completely filled tray.) It is to be appreciated that the removal component 308 can operate independent of the loader 306 and does not need to be integrated with the loader 306.

The loader 306 place removed die into the empty tray 302. Placement of die upon an empty tray 302 is one manner of organizing dice together; however, it is to be appreciated there are other manners of organizing dice together.

Placement of dice onto the empty tray 302 is preferably conducted with a high level of precision. It is possible that the number of available dice is not equal to the spaces available. For example, the empty tray 302 could hold about 2048 dice; however, there are only about 1548 dice available. Therefore, the empty tray 302 is filled with the 1548 dice by the loader 306, which creates a filled tray 310. At this point, the partially filled tray 310 can wait for another group of dice or the partially filled tray 310 can continue to other components of the system 200 of FIG. 2.

The loader 306 can fill the empty tray 302 at a specified temperature and/or pressure. Other devices can use the same temperature and/or pressure in the system 200 of FIG. 2. Since the system 200 of FIG. 2 can employ high precision techniques, it can be beneficial to operate at a constant temperature and/or pressure. This is because changes in temperature and/or pressure can cause changes in the physical location of objects.

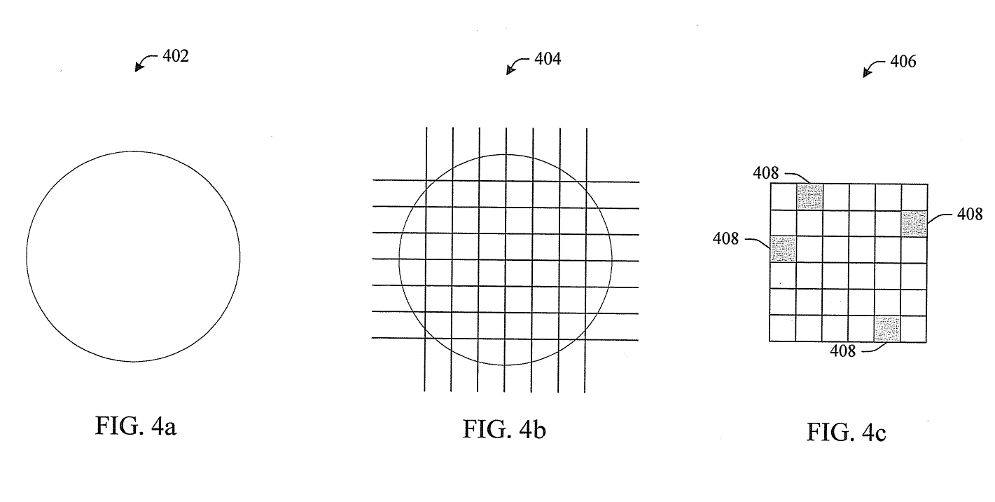

FIG. 4a-FIG. 4c discloses an example operation upon a wafer in conjunction with the loader cell 202 of FIG. 3. FIG. 4a discloses an un-diced wafer 402 that would enter an assembly area. FIG. 4b discloses the wafer 402 of FIG. 4a in a diced format 404. Using one possible dicing technique, there is creation of thirty-two square dice from the original wafer 402 of FIG. 4a. The dice are accurately placed on a wafer tray 406 disclosed in FIG. 4c. While the wafer tray 406 is shown with thirty-six slots for dice, it is to be appreciated that the wafer tray 406 can have a plurality of different spaced for holding dice (e.g., about 1024 die spaces, about 2048 die spaces). Furthermore, the wafer tray 406 does not have to have an equal number of columns and rows (e.g., six columns and eight rows). Since there are 32 square dice and 36 wafer portion slots, open slots 408 can be filled by another dicing or by other components in the system 200 of FIG. 2.

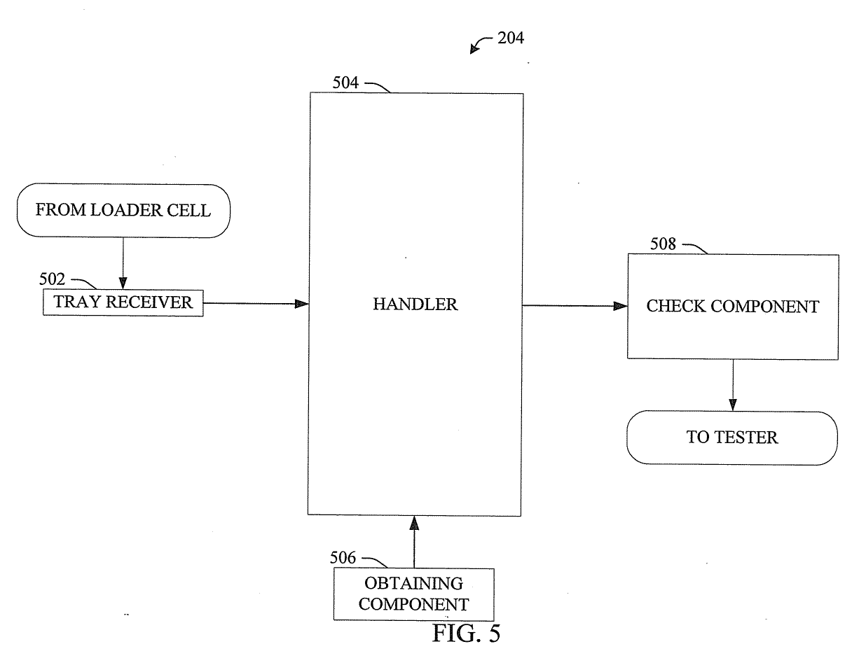

FIG. 5 discloses an example consolidator cell 204 of FIG. 2. A tray receiver 204 obtains a tray that enters into the consolidator cell 204. The tray receiver 502 can use internal logic when processing a tray. For example, the tray receiver 502 can determine how many dice are present in a tray and how many open spaces there are in the tray. This information can travel to a handler 504 that attempts to fill the tray.

The tray receiver 502 can also contain error-checking logic. For example, a tray can enter the consolidator cell 204 in an empty state. It can be inefficient for the consolidator cell 204 to fill an empty try; completely filling a tray can waste consolidator resources in doing the same task that can be done by a loader cell 202 of FIG. 2. Therefore, the tray receiver can identify an empty tray and transfer the empty tray to a loading cell. In another embodiment, the tray receiver contains logic to identify a filled tray. Therefore, there is no need for consolidation and the tray receiver can transfer the empty tray directly to the tester 206 of FIG. 2.

The handler 504 fills a tray with die from different wafers. According to one embodiment, the handler 504 removes dice from received trays. For example, the handler 504 can receive a first tray from the loader cell 202 of FIG. 3 that is about 50% filled. The handler can hold the dice from this tray. The handler 504 then receives a second tray from the loader cell 202 of FIG. 3 that is 20% filled. The handler 504 removes the dice from that tray. The handler 504 receives a third tray from the loader cell 202 of FIG. 3 that is 40% filled. The handler 504 can add the dice from the first tray and two-thirds of the dice from the second tray to the third tray.

Trays that have had dice taken can be returned to the loader cell 202 of FIG. 3. According to another embodiment, the handler 504 holds the trays as well as the dice. In a further embodiment, the handler 504 places dice together that are from the same test iteration. For example, dice that have never been tested before are placed on the same tray. According to one embodiment, dice can be held to a tray by a vacuum mechanism. Furthermore, there can be an auto alignment feature integrated in the tray to assure dice stay in an accurate position within a specified tolerance.

An obtaining component 506 allows the handler 504 to gather dice that have already been tested, but were not from a full tray. For example, the sorter cell 208 of FIG. 2 can send successful dice back to the consolidator cell 204. The obtaining component collects the cells sent by the sorter cell 208 of FIG. 2. The obtaining component 506 can configure to gather the dice alone, dice placed on a tray, or other configurations.

Filled trays can transfer to a check component 508 that determines if the trays are filled. If there is a tray that is not properly filled, then the check component 508 can return the tray back to the handler 504. Furthermore, the check component 508 can configure to operate error checking functions upon the handler 504 or any other device of the system 200 of FIG. 2. For example, the handler 504 can miss a corner slot of a tray and not place a die in that slot. The check component 508 can determine why this took place (e.g., a handler 504 placement mechanism is not properly aligned) and correct the error (e.g., re-align the placement mechanism.)

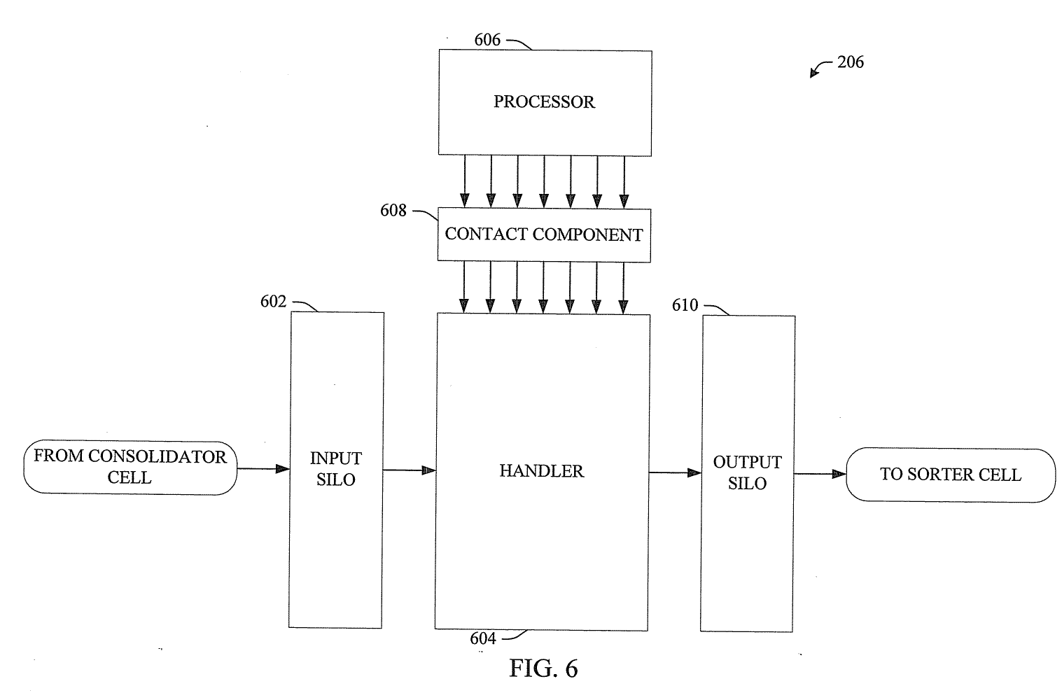

FIG. 6 discloses an example tester 206 of FIG. 2. The tester 206 performs a diagnostic check on at least two dice simultaneously. Filled trays from the consolidator cell 204 of FIG. 5 travel to an input silo 602 to wait for testing. A common input silo 602 can hold about twenty trays to about forty trays. The input silo 602 operates to allow for continuous movement of trays into a temperature chamber 604 for testing to allow for the maximum amount of tests to take place of a specified period. The input silo 602 is an example of a receiving component.

When a time comes for a tray to be tested, the tray travels to a handler 604 which includes a temperature chamber. The temperature chamber in handler 604 can hold a tray at a specified climate that can influence the outcome of a test upon the die. For example, the temperature chamber operates between −55 C to +180 C. A processor 606 informs the handler 604 of what climate in which to hold the tray.

The processor 606 is in communication with at least one contact component 608. The processor 606 can include internal memory of how to perform a test and internal logic on how to interpret various results that can be encountered during a test. Various errors can take place during testing and the processor 606 can function to both identify and correct encountered errors. The handler 604 aligns and presents a test tray to the contact component 608. For example, handler can present a tray with about 256 dice tiled or about 1024 dice in parallel.

Furthermore, the processor 606 is device type specific. One processor type is designed to optimally test only memory devices while another is designed to optimally test logic devices. If one test cell is used to test memory, then a different test cell will be used to test logic; cells are not the same. Programs of the tests to be performed (e.g., Sort 1, Sort 2, etc) are loaded into processor 606 and will be used to electrically determine if a die is good or bad based on parameters.

Testing commonly takes place through the application of contacting individual dice with the contact component 608. In one embodiment, the contact component 608 includes probes that connect with circuitry of individual dice. When connected, signals can transfer from the processor 606 to the dice and the processor 606 interprets the results of applied signals.

Contact of die through the contact component 608 can take place through multiple embodiments. According to one embodiment, the contact component 608 consists of multiple contact sets, which connect to all the dies on the tray simultaneously.

A tray containing tested dice moves from the handler 604 to an output silo 610. The output silo 610 functions in a similar manner to the input silo 602. The output silo 610 can continuously transfer trays to the sorter cell 208 of FIG. 2.

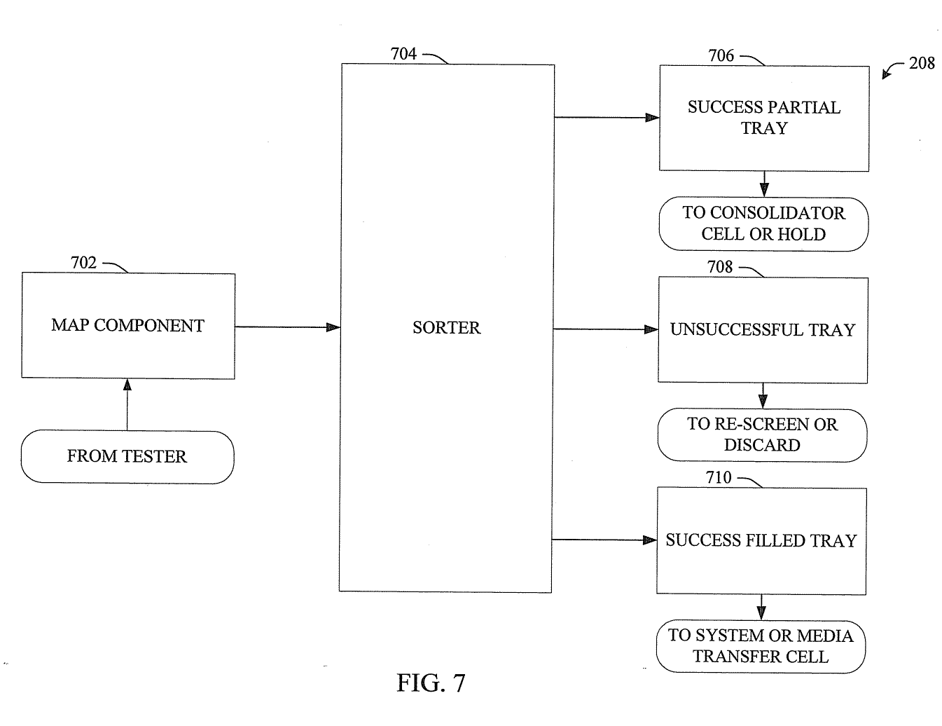

FIG. 7 discloses an example sorter cell 208 of FIG. 2. A tray that has completed testing transfers to a map component 702. The map component 702 functions to keep track of which dice were tested successfully and which dice were tested without success. While the map component 702 is shown as part of the sorter cell 208, it can function in other locations. For example, the map component 702 can operate as part of the tester 206 of FIG. 6 prior to entering the output silo 610 of FIG. 6. A receiving component can integrate into the map component, similar to the tray receiver 502 of FIG. 5.

The map component 702 can be in communication with a sorter 704. The sorter 704 identifies which dice are successful dice and which are unsuccessful dice. Based on the identification, the sorter 704 separates dice based on the success the die had on the test performed by the tester 206 of FIG. 6. According to one possible embodiment, the map component 702 sends a message to the sorter 704 as to which dice are successful and unsuccessful. In another embodiment, the map component 702 places map information on a tray that holds die (e.g., information is recorded onto memory located on a tray.) The sorter 704 reads this information and separates successful dice from unsuccessful dice.

According to one embodiment, the sorter 704 can remove unsuccessful dice from the tray and leave successful dice on the tray. In another embodiment, the sorter 704 removes successful dice while leaving unsuccessful dice. In a further embodiment, the sorter 704 possesses an alignment system, commonly an optical system or mechanical system.

A common occurrence can be that there are unsuccessful dice in a tray that are removed. It can be beneficial to further process trays that are completely filled with successful die. Therefore, successful dice can be consolidated together to create full trays. A success partial tray 706 (e.g., a tray where some slots contain a successful die and others are empty) can either transfer to the consolidator cell 204 of FIG. 5 or be held in the sorter cell 208.

It can be detrimental to re-test a die once it has been successfully tested. For example, a test can leave a hole in circuitry of a die and more holes can lead to difficulties in wire bonding 118, 122, and 126 of FIG. 1. Therefore, the success partial tray 706 can be held in the sorter cell 208 where dice can combine with other successful dice. However, there can be situations where the dice should return to the consolidator to join with other dice and be re-tested. For example, there could be a die that if not placed in an MCP in a specific amount of time, then the die fails. Therefore, as opposed to holding the dice where the dice could fail and the failure would not be known until after placement in the MCP, the dice can return to the consolidator and be re-tested.

There can be an unsuccessful tray 708 that includes dice that failed the test. According to one possible embodiment, unsuccessful dice are re-screened. The re-screening can take place within the sorter cell 208 or in another location. Re-screening can be an action that attempts to determine why a die failed. Based on the determination, the die can be re-tested or scrapped. For example, the re-screen can determine an incorrect contact was made with the die that resulted in the failed test. The die can be re-tested to determine if the die is actually an unsuccessful die or if the die failed because of a bad test.

According to another embodiment, the unsuccessful cells can be scrapped. This eliminates bad dice from becoming part of the MCP without further testing. There can be integration between scrapping and re-screening dice. For example, if a die has been tested once before, it can be re-screened. However, if the die has been tested twice and failed, then it can be assumed the die is unsuccessful and the die can be scrapped.

A success filled tray 710 (e.g., a tray where slots contain a successful die) can move on to a next location. A next location can be a number of different locations depending on a particular configuration of a system 200 of FIG. 2. For example, the next location can be another system, where the success filled tray 710 travels to a loader cell. In another example, the success filled tray 710 travels to a media transfer cell 210 of FIG. 2.

While one embodiment has the success filled tray 710 completely filled (e.g., 1024 dice in 1024 spaces), it is possible that a tray with a relatively small number of open slots to still be considered at success filled tray 710. The sorter 704 can contain internal logic to determine what percentage of open slots can be present to consider a tray a success filled tray 710.

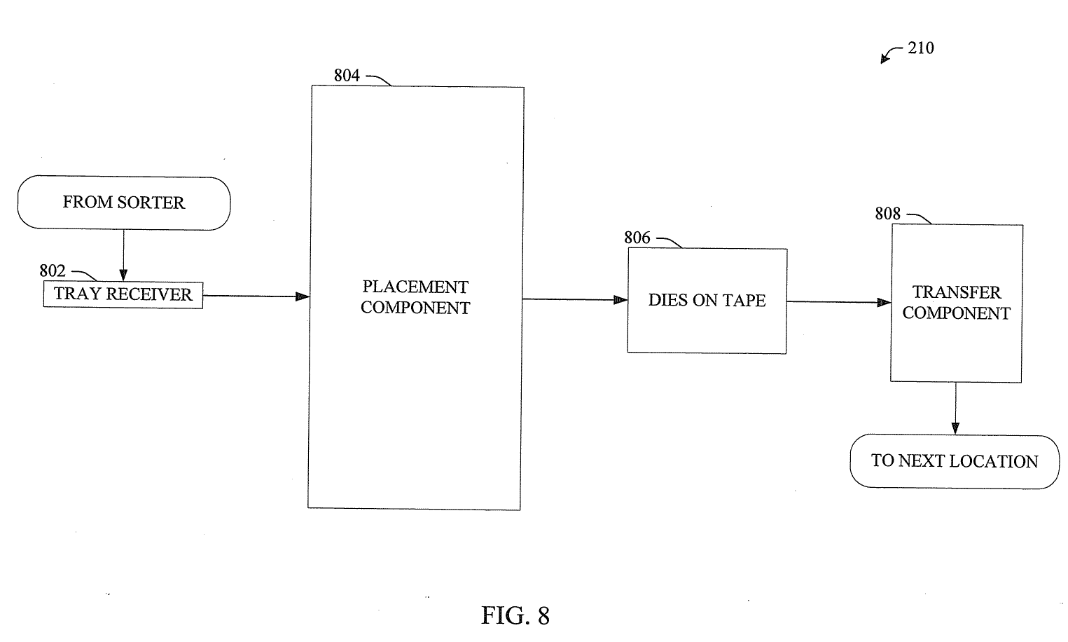

FIG. 8 discloses an example media transfer cell 210 of FIG. 2. A tray receiver 802 obtains a tray transferred from the sorter cell 208 of FIG. 7. The tray moves to a placement component 804. The placement component 804 returns die to tape; this can be seen as a reversal of the removal of tape that took place in context of the loader 306 of FIG. 3. This allows for units outside of the system 200 of FIG. 2 to function easier since the dice are in the same state when the dice enter the system 200 of FIG. 2 as when the dice exit. The dice on tape 806 move to a transfer component 808 that sends the dice on tape 806 to components outside of the system 200 of FIG. 2.

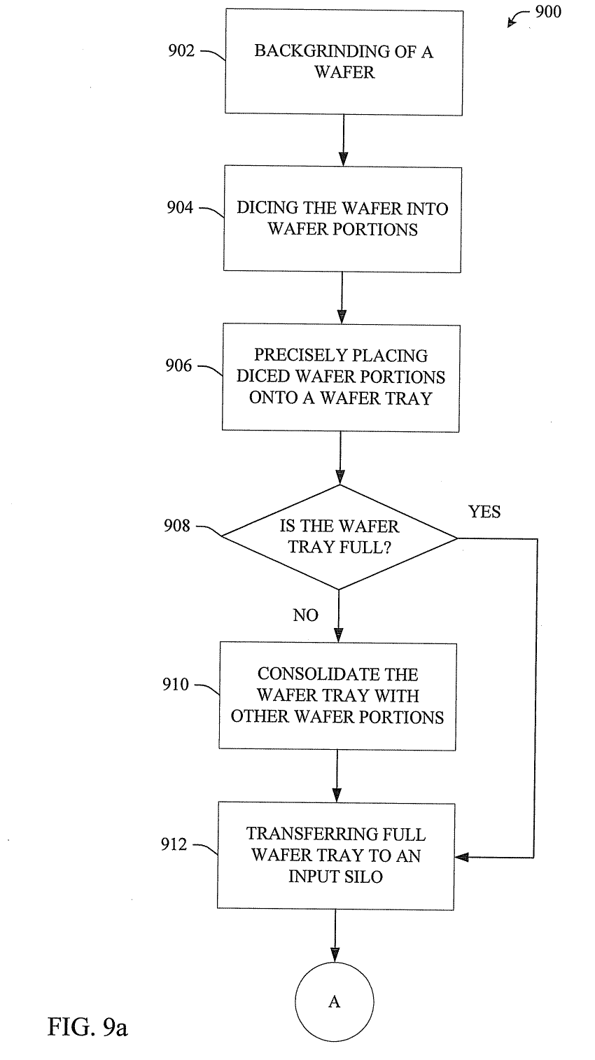

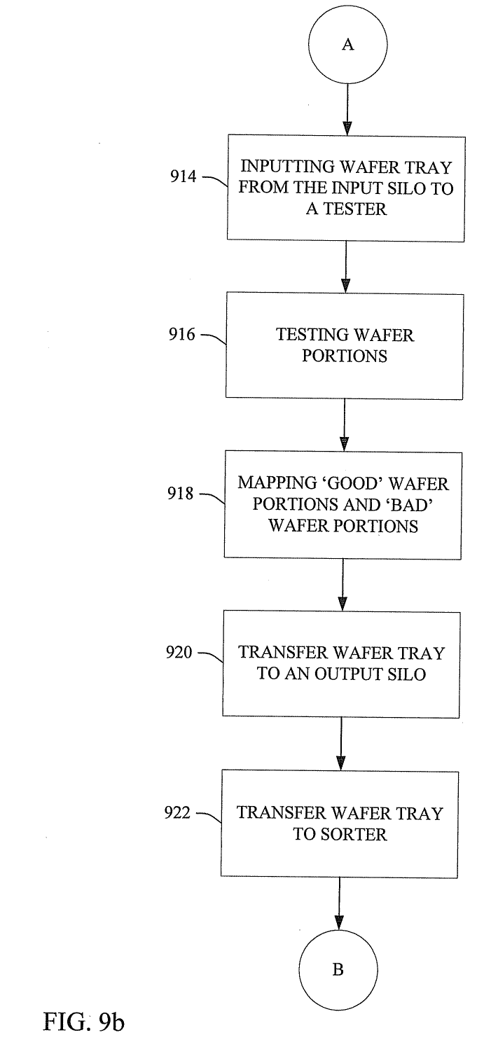

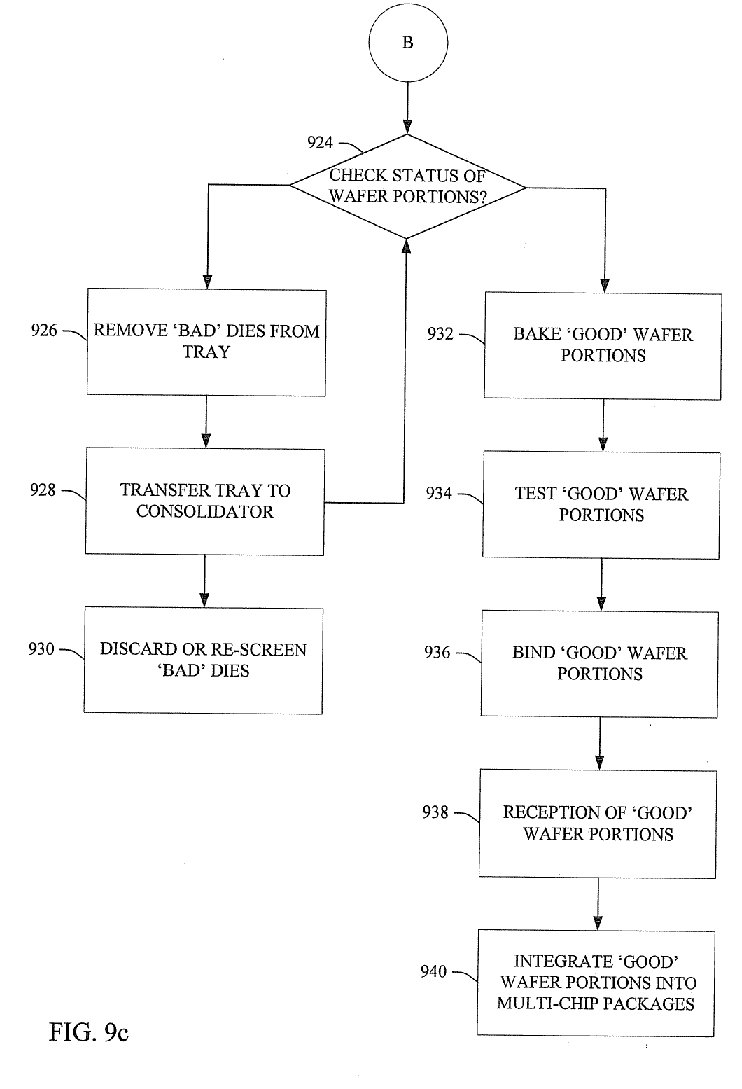

FIG. 9a-FIG. 9c disclose an example methodology 900 practicing some aspects of the disclosed innovation, including testing wafer portions. A wafer is initially background 902 to a desired uniform thickness. Having a wafer at a single thickness can allow for easier manipulation of the wafer in later actions. Furthermore, there can be maximum height requirements of components operating actions of the methodology 900. Therefore, the wafer is commonly background to assure that the wafer can make minimum clearance. During backgrinding, it is common to affix tape to the other side of the wafer (e.g., the side that exposes circuitry.)

A background wafer is diced into smaller wafer portions 904. One manner in which to dice a wafer is through sawing the wafer at various angles to create wafer portions. The saw can accurately cut to allow alignment to the edge of a wafer (e.g., cutting at an edge to maximize an amount of viable wafer portions.)

According to one embodiment, there can be a number of tolerances available for sawing of the wafer. For example, tolerance toward the center of the die should be plus/minus ten μm. On an unsawn wafer, spaces between the dice are called streets. Positional tolerance can be accurate to plus/minus five μm to the center of a street. Furthermore, the thickness of the saw blade can be a tolerance of plus/minus five μm.

While the term sawing is used to describe the dicing of a wafer into smaller wafer portions, there can be other methods used aside from sawing. For example, a laser can divide the wafer into wafer portions. In another example, a laser/water hybrid can divide the wafer into smaller wafer portions.

Once a wafer is properly diced, the wafer portions are precisely placed on a wafer tray 906. A common wafer tray can hold a plurality of wafer portions (e.g., about 1024, about 2048, etc . . . ). Actions later in the methodology 900 can require a great amount of precision, since there acts interact with relatively large numbers of wafer portions. Therefore, it can be important that wafers be placed on a tray with accuracy.

Furthermore, having a maximum amount of wafer portions on a tray allows for testing more wafer portions in less testing instances. Since there is commonly a cost associated with running a testing instance, the fewer number of testing instances run, the lower the overall cost. Accurate placement of wafer portions upon a tray allow for maximization of space on the tray and a lower total cost.

Once diced, wafer portions are placed on a wafer tray 906, a check is performed to determine if the tray is full 908. There are numerous reasons to assure that there is a full tray 908 when testing. One reason for assuring that a wafer tray is full 908 is to maximize the cost of operation. Similarly, not having precision placement of wafer portions upon a tray can be detrimental by having empty spaces on a wafer tray and this can add to cost since there could have been wafer portions tested in the empty spaces.

Furthermore, it is possible that a component that physically tests the wafer portions could be damaged if the wafer tray is not full. For example, a contact could lower to test the die. However, if there is no die, the contact can be configured to continue down to touch the tray. Touching of the wafer tray could cause damage to the contact. Therefore, a full tray can allow for minimal interaction between a contact and a wafer tray.

If a tray is not filled, then a consolidation is attempted to bring other wafer portions onto the tray 910. This means that a tray can be filled with wafer portions that originate from different wafers. Wafer placement can be done in a similar manner as original placement of wafers upon a wafer tray 906. This allows for maximization of space of the tray and reduced risk of damage to a testing contact.

Consolidated wafer portions can originate from a number of different locations. According to one embodiment, consolidation combines wafer portions that have never been tested. In another embodiment, consolidation adds wafer portions that are considered ‘bad’ die (e.g., des that do not meet testing requirements) that have been re-screened and given clearance to be provided another testing session.

A tray filled with wafers is transferred to an input silo 912. The input silo holds trays prior to testing. The silo operates in order to allow a continuous stream of trays to be tested one after another. This allows for less down time and the completion of more tests in a specific window of time. Movement of the silo from one location to another, for example from handler 604 to sorter 704 can all take place using a robotic mechanism.

The filled wafer tray transfers to a tester 914. Once at the tester, testing takes place 916, which commonly is the application of a metal contact to an individual wafer portion. According to one embodiment, the application of the metal contact can align with the edge of the tray to ensure dice are accurately tested. In another embodiment, the application of the metal contact can align with the corner of each of the die to ensure dice are accurately tested.

Once testing is complete, there is mapping of ‘good’ die against ‘bad’ die 918. Since a common tray will have a relatively large number of die, it is important that there is a mechanism in place to keep track of which dice are useable and which ones are not. A mapping allows for later actions of the methodology 900 to determine which wafer portions have which characteristics.

While the methodology 900 discloses a distinction between ‘good’ and ‘bad die, it is to be appreciated that there can be other distinctions processed by the methodology 900. For example, testing of the wafer portions can be the application of three different tests. In one embodiment, a ‘bad’ die is a wafer portion that failed one of the three tests. In another embodiment, wafer portions can be designated based on how the wafer performed on each test. For example, a wafer portion that fails a first test and passes the other two can obtain a designation of ‘T1-T2+T3+’. This provides more information then a mere ‘bad’ designation.

A mapped wafer tray transfers to an auxiliary component, for example an output silo 920, which can function in a similar manner as operation within the input silo. Once properly processed (e.g., the tested tray waits in line,) the filled tray transfers to a sorter 922. A check is then performed to determine what types of wafer portions are included in the tray 924. According to one embodiment, a tray with at least one ‘bad’ die and/or an open space transfers to action 926. In another embodiment, a tray with no ‘bad’ die, but with an open space does not transfer to action 926. Through the check 924, wafer portions sort into categories (e.g., passed, failed, etc.) Sorting still takes place when wafer portions are of the same type; the wafer portions sort into one category.

If a tray does not meet requirements of the check 924, the ‘bad’ wafer portions are removed from the tray 926 if there are ‘bad’ wafer portions. The tray then transfers to a consolidator where the ‘good’ wafer portions are combined with other wafer portions 928. A consolidated tray can return to check 924.

The wafer portions designated as ‘bad’ can be re-screened or scrapped 930. Re-screening means there can be test to determine why there was a failure and a possible to attempt to correct the error. Successfully re-screened wafer portions can re-enter the methodology at the consolidator action. ‘Bad’ wafer portions can be scrapped, commonly because they cannot be repaired or because the methodology is not equipped to handle repairs of the ‘bad’ wafer portions.

If the wafer tray is filled with ‘good’ wafer portions, then the wafers continue to a baking action 932 that prepares them for addition to multi-die units. The wafer portions can have another battery of tests take place to assure that there are ‘good’ dice on the trays 934. The good dice are then bound onto a film frame 936. Tested die components are received 938, for example, the die components are received by a construction component. The ‘good’ wafer portions become integrated into a multi-wafer portion component through construction of a multi-wafer portion component 940. According to one embodiment, an individual die becomes part of an independent multi-chip package (e.g., five ‘good’ dice are placed into five MCP so there is one die for one MCP).

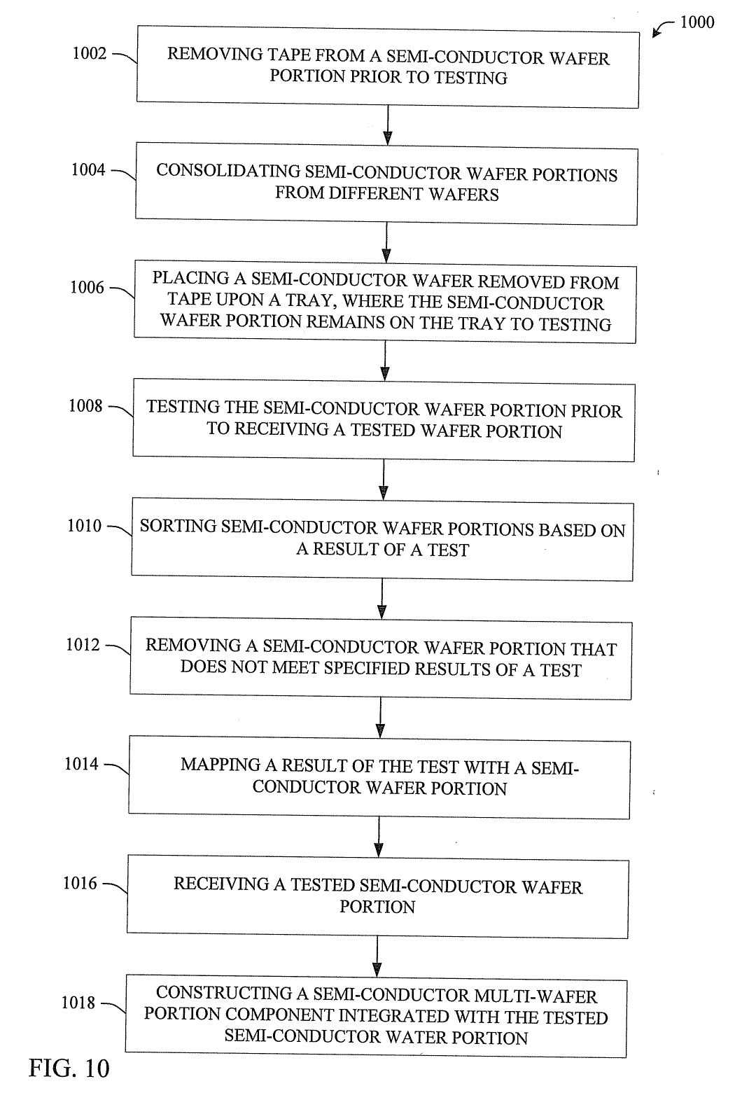

FIG. 10 discloses an example methodology 1000 for construction of a multi-wafer portion component construction. Action 1002 is removing tape from a semi-conductor wafer portion prior to testing. Removal of the tape allows different wafer portions to separate from an original wafer configuration. There can be consolidating semi-conductor wafer portions for different wafers 1004. Consolidation includes grouping similar wafer portions together. This can take place through use of an automatic machine (e.g., robotic arm.)

Placing a semi-conductor wafer portion removed from tape upon a tray, where the semi-conductor wafer portion remains on the tray to testing 1006 occurs. Once wafer portions are grouped, they can be placed on a tray so they are not separated during a test and results of the test can be tracked relatively easily. There is testing the semi-conductor wafer portion prior to receiving a tested wafer portion 1008. Testing determines if a wafer portion should be part of a multi-chip package; an example test is a sort test.

Sorting semi-conductor wafer portions based on results of a test 1010 takes place. Sorting allows for other actions in the methodology 1000 to distinguish between ‘good’ dies (e.g., dies that should become part of a multi-chip package) and ‘bad’ dies (e.g., dies that should not become part of a multi-chip package.) According to one embodiment, sorting is physically separating different dies can be distinguished. In one instance, if are no ‘bad’ dies, then dies are sorted by being classified as good.

Action 1012 is removing a semi-conductor wafer portion that does not meet specified results of a test. Physical removal allows other actions in the methodology 1000 to operate without concern that the actions are operating with ‘bad’ dies. Specified results can be a standard that is specific to a methodology 1000. For instance, a multi-chip package for a laptop can have different wafer requirements then a multi-chip package for a coffeemaker; thus, standard for removal can be different based on where the die will ultimately be placed.

There is mapping a result of the test with a semi-conductor wafer portion 1014. According to one embodiment, mapping is retaining a record of die results from testing. Receiving a tested semi-conductor wafer portion 1016 occurs. This can be performed by a unit that can hold die. This can include receiving at least one wafer portion from the methodology 1000 as well as receiving at least one wafer portion from an at least one other auxiliary location operating a methodology (e.g., another version of methodology 1000, a different methodology, etc. . . . ) There is constructing a semi-conductor multi-wafer portion component integrated with the tested semi-conductor wafer portion 1018. According to one embodiment, construction is placing wafer portions upon a substrate base.

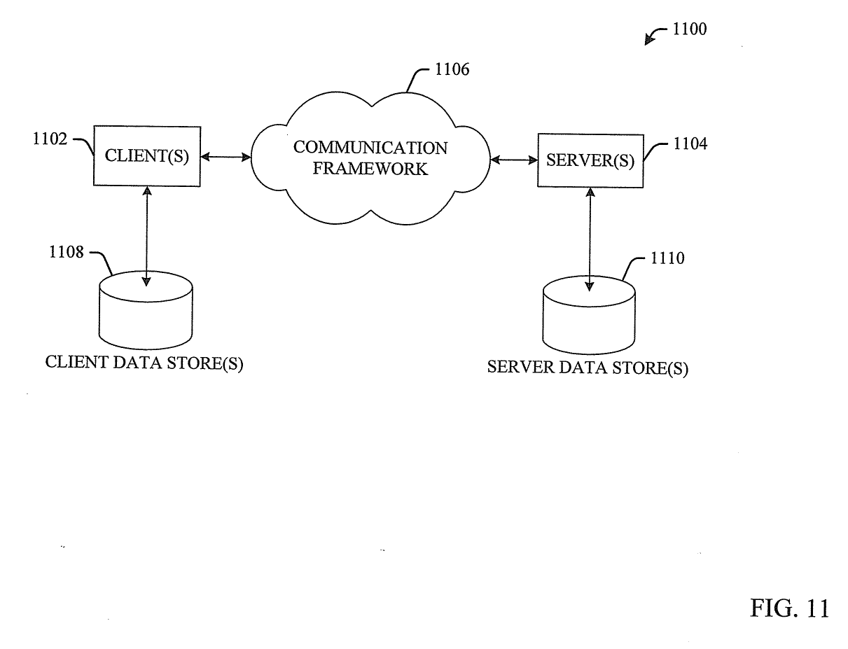

Referring now to FIG. 11, there is illustrated a schematic block diagram of a computing environment 1100 in accordance with the subject innovation. The system 1100 includes one or more client(s) 1102. The client(s) 1102 can be hardware and/or software (e.g., threads, processes, computing devices). The client(s) 1102 can house cookie(s) and/or associated contextual information by employing the innovation, for example.

The system 1100 also includes one or more server(s) 1104. The server(s) 1104 can also be hardware and/or software (e.g., threads, processes, computing devices). The servers 1104 can house threads to perform transformations by employing the innovation, for example. One possible communication between a client 1102 and a server 1104 can be in the form of a data packet adapted to be transmitted between two or more computer processes. The data packet may include a cookie and/or associated contextual information, for example. The system 1100 includes a communication framework 1106 (e.g., a global communication network such as the Internet) that can be employed to facilitate communications between the client(s) 1102 and the server(s) 1104.

Communications can be facilitated via a wired (including optical fiber) and/or wireless technology. The client(s) 1102 are operatively connected to one or more client data store(s) 1108 that can be employed to store information local to the client(s) 1102 (e.g., cookie(s) and/or associated contextual information). Similarly, the server(s) 1104 are operatively connected to one or more server data store(s) I l 10 that can be employed to store information local to the servers 1104.

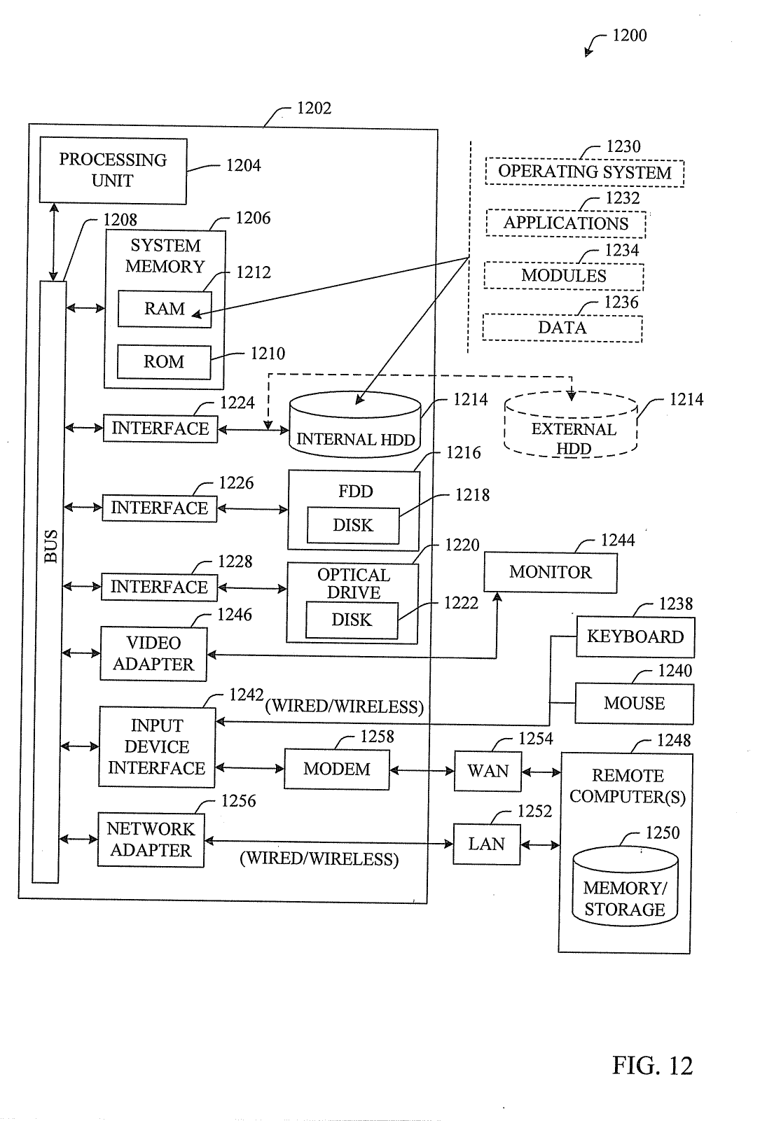

Referring now to FIG. 12, there is illustrated a block diagram of a computer operable to execute the disclosed architecture. In order to provide additional context for various aspects of the subject innovation, FIG. 12 and the following discussion are intended to provide a brief, general description of a suitable computing environment 1200 in which the various aspects of the innovation can be implemented. While the innovation has been described above in the general context of computer-executable instructions that may run on one or more computers, those skilled in the art will recognize that the innovation also can be implemented in combination with other program modules and/or as a combination of hardware and software.

Generally, program modules include routines, programs, components, data structures, etc., that perform particular tasks or implement particular abstract data types. Moreover, those skilled in the art will appreciate that the inventive methods can be practiced with other computer system configurations, including single-processor or multiprocessor computer systems, minicomputers, mainframe computers, as well as personal computers, hand-held computing devices, microprocessor-based or programmable consumer electronics, and the like, each of which can be operatively coupled to one or more associated devices.

The illustrated aspects of the innovation may also be practiced in distributed computing environments where certain tasks are performed by remote processing devices that are linked through a communications network. In a distributed computing environment, program modules can be located in both local and remote memory storage devices.

A computer typically includes a variety of computer-readable media. Computer-readable media can be any available media that can be accessed by the computer and includes both volatile and nonvolatile media, removable and non-removable media. By way of example, and not limitation, computer-readable media can comprise computer storage media and communication media. Computer storage media includes volatile and nonvolatile, removable and non-removable media implemented in any method or technology for storage of information such as computer-readable instructions, data structures, program modules or other data. Computer storage media includes, but is not limited to, RAM, ROM, EEPROM, flash memory or other memory technology, CD-ROM, digital versatile disk (DVD) or other optical disk storage, magnetic cassettes, magnetic tape, magnetic disk storage or other magnetic storage devices, or any other medium which can be used to store the desired information and which can be accessed by the computer.

Communication media typically embodies computer-readable instructions, data structures, program modules or other data in a modulated data signal such as a carrier wave or other transport mechanism, and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above should also be included within the scope of computer-readable media.

With reference again to FIG. 12, the example environment 1200 for implementing various aspects of the innovation includes a computer 1202, the computer 1202 including a processing unit 1204, a system memory 1206 and a system bus 1208. The system bus 1208 couples system components including, but not limited to, the system memory 1206 to the processing unit 1204. The processing unit 1204 can be any of various commercially available processors. Dual microprocessors and other multi-processor architectures may also be employed as the processing unit 1204.

The system bus 1208 can be any of several types of bus structure that may further interconnect to a memory bus (with or without a memory controller), a peripheral bus, and a local bus using any of a variety of commercially available bus architectures. The system memory 1206 includes read-only memory (ROM) 1210 and random access memory (RAM) 1212. A basic input/output system (BIOS) is stored in a non-volatile memory 1210 such as ROM, EPROM, EEPROM, which BIOS contains the basic routines that help to transfer information between elements within the computer 1202, such as during start-up. The RAM 1212 can also include a high-speed RAM such as static RAM for caching data.

The computer 1202 further includes an internal hard disk drive (HDD) 1214 (e.g., EIDE, SATA), which internal hard disk drive 1214 may also be configured for external use in a suitable chassis (not shown), a magnetic floppy disk drive (FDD) 1216, (e.g., to read from or write to a removable diskette 1218) and an optical disk drive 1220, (e.g., reading a CD-ROM disk 1222 or, to read from or write to other high capacity optical media such as the DVD). The hard disk drive 1214, magnetic disk drive 1216 and optical disk drive 1220 can be connected to the system bus 1208 by a hard disk drive interface 1224, a magnetic disk drive interface 1226 and an optical drive interface 1228, respectively. The interface 1224 for external drive implementations includes at least one or both of Universal Serial Bus (USB) and IEEE 1394 interface technologies. Other external drive connection technologies are within contemplation of the subject innovation.

The drives and their associated computer-readable media provide nonvolatile storage of data, data structures, computer-executable instructions, and so forth. For the computer 1202, the drives and media accommodate the storage of any data in a suitable digital format. Although the description of computer-readable media above refers to a HDD, a removable magnetic diskette, and a removable optical media such as a CD or DVD, it should be appreciated by those skilled in the art that other types of media which are readable by a computer, such as zip drives, magnetic cassettes, flash memory cards, cartridges, and the like, may also be used in the example operating environment, and further, that any such media may contain computer-executable instructions for performing the methods of the innovation.

A number of program modules can be stored in the drives and RAM 1212, including an operating system 1230, one or more application programs 1232, other program modules 1234 and program data 1236. All or portions of the operating system, applications, modules, and/or data can also be cached in the RAM 1212. It is appreciated that the innovation can be implemented with various commercially available operating systems or combinations of operating systems.

A user can enter commands and information into the computer 1202 through one or more wired/wireless input devices, e.g., a keyboard 1238 and a pointing device, such as a mouse 1240. Other input devices (not shown) may include a microphone, an IR remote control, a joystick, a game pad, a stylus pen, touch screen, or the like. These and other input devices are often connected to the processing unit 1204 through an input device interface 1242 that is coupled to the system bus 1208, but can be connected by other interfaces, such as a parallel port, an IEEE 1394 serial port, a game port, a USB port, an IR interface, etc.

A monitor 1244 or other type of display device is also connected to the system bus 1208 via an interface, such as a video adapter 1246. In addition to the monitor 1244, a computer typically includes other peripheral output devices (not shown), such as speakers, printers, etc.

The computer 1202 may operate in a networked environment using logical connections via wired and/or wireless communications to one or more remote computers, such as a remote computer(s) 1248. The remote computer(s) 1248 can be a workstation, a server computer, a router, a personal computer, portable computer, microprocessor-based entertainment appliance, a peer device or other common network node, and typically includes many or all of the elements described relative to the computer 1202, although, for purposes of brevity, only a memory/storage device 1250 is illustrated. The logical connections depicted include wired/wireless connectivity to a local area network (LAN) 1252 and/or larger networks, e.g., a wide area network (WAN) 1254. Such LAN and WAN networking environments are commonplace in offices and companies, and facilitate enterprise-wide computer networks, such as intranets, all of which may connect to a global communications network, e.g., the Internet.

When used in a LAN networking environment, the computer 1202 is connected to the local network 1252 through a wired and/or wireless communication network interface or adapter 1256. The adapter 1256 may facilitate wired or wireless communication to the LAN 1252, which may also include a wireless access point disposed thereon for communicating with the wireless adapter 1256.

When used in a WAN networking environment, the computer 1202 can include a modem 1258, or is connected to a communications server on the WAN 1254, or has other means for establishing communications over the WAN 1254, such as by way of the Internet. The modem 1258, which can be internal or external and a wired or wireless device, is connected to the system bus 1208 via the serial port interface 1242. In a networked environment, program modules depicted relative to the computer 1202, or portions thereof, can be stored in the remote memory/storage device 1250. It will be appreciated that the network connections shown are example and other means of establishing a communications link between the computers can be used.

The computer 1202 is operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, restroom), and telephone. This includes at least Wi-Fi and Bluetooth™ wireless technologies. Thus, the communication can be a predefined structure as with a conventional network or simply an ad hoc communication between at least two devices.

Wi-Fi, or Wireless Fidelity, allows connection to the Internet from a couch at home, a bed in a hotel room, or a conference room at work, without wires. Wi-Fi is a wireless technology similar to that used in a cell phone that enables such devices, e.g., computers, to send and receive data indoors and out; anywhere within the range of a base station. Wi-Fi networks use radio technologies called IEEE 802.11 (a, b, g, etc.) to provide secure, reliable, fast wireless connectivity. A Wi-Fi network can be used to connect computers to each other, to the Internet, and to wired networks (which use IEEE 802.3 or Ethernet). Wi-Fi networks operate in the unlicensed 2.4 and 5 GHz radio bands, at an 11 Mbps (802.11a) or 54 Mbps (802.11b) data rate, for example, or with products that contain both bands (dual band), so the networks can provide real-world performance similar to the basic 10BaseT wired Ethernet networks used in many offices.

What has been described above includes examples of the subject innovation. It is, of course, not possible to describe every conceivable combination of components or methodologies for purposes of describing the subject innovation, but one of ordinary skills in the art may recognize that many further combinations and permutations of the subject innovation are possible. Accordingly, the subject innovation is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A semi-conductor die test system, comprising:
a receiving component that obtains at least about 256 semi-conductor die grouped together; and
a test component that performs a diagnostic check on at least about 256 semi-conductor die obtained by the receiving component.

2. The system of claim 1, wherein the receiving component obtains at least about 1024 semi-conductor die grouped together.

3. The system of claim 2, wherein the test component performs a diagnostic check on at least about 1024 semi-conductor die obtained by the receiving component.

4. The system of claim 1, wherein the testing component performs a diagnostic check on at least two semi-conductor die during one diagnostic check session.

5. The system of claim 1, further comprising a sorter that separates die based on a result of the diagnostic check.

6. The system of claim 1, further comprising a handler that groups together die from at least two wafers, wherein there is performance of the diagnostic check upon at least some of the die.

7. The system of claim 1, further comprising a placement component that places at least one tested die on tape.

8. The system of claim 1, further comprising a loader that places at least about 256 die onto a tray within a specified precision tolerance level, wherein at least about 256 die from the tray is subject to the diagnostic check.

9. The system of claim 8, further comprising a removal component that removes at least about 256 die from tape prior to operation of the loader.

10. The system of claim 1, further comprising a map component that tracks a result of the diagnostic check upon semi-conductor die.

11. The system of claim 1, further comprising a construction component that creates a multi-die package that includes at least one die subjected to the diagnostic check.

12. A method for multi-wafer portion component construction, comprising:
receiving a tested semi-conductor wafer portion; and
constructing a semi-conductor multi-wafer portion component integrated with the tested semi-conductor wafer portion.

13. The method of claim 12, further comprising consolidating semi-conductor wafer portions from different wafers.

14. The method of claim 12, further comprising sorting semi-conductor wafer portions based on a result of a test.

15. The method of claim 12, further comprising removing a semi-conductor wafer portion that does not meet specified results of a test.

16. The method of claim 12, further comprising testing the semi-conductor wafer portion prior to receiving the tested wafer portion.

17. The method of claim 16, further comprising removing tape from the semi-conductor wafer portion prior to testing.

18. The method of claim 17, further comprising placing a semi-conductor wafer removed from tape upon a tray, wherein the semi-conductor wafer portion remains on the tray to testing.

19. The method of claim 16, further comprising mapping a result of the test with the semi-conductor wafer portion.

20. A system for creating a multi-wafer portion component, comprising:
means for independently testing at least about two semi-conductor wafer portions; and
means for combining at least two semi-conductor tested wafers to form a multi-wafer portion component.
